(19) United States
(12) Patent Application Publication
(10) Pub. No.: US 2006/0103396 A1
(43) Pub. Date: May 18, 2006

(54) Method and apparatus for non-contact testing of microcircuits

(76) Inventors: Michael R. T. Tan, Menlo Park, CA (US); Michael Nystrom, San Jose, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/976,694

(22) Filed: Oct. 28, 2004

(51) Int. Cl. G01R 31/305

(52) U.S. Cl. 324/751

(57) ABSTRACT

A non-contact test method and apparatus is disclosed that can be used to test OLED flat panel TFTs. An ionized gas is used to supply current to the device under test.

### BACKGROUND OF THE INVENTION

There are a number of techniques for measuring voltages on liquid crystal(LCD) flat panel displays which comply with the requirement that there be no electrical contact on the active area of the flat panel display to avoid contamination of the electrode surfaces although the electrical contact may be made at the edges of the flat panel display. However, in order to test active areas of an organic light emitting diode (OLED) display, it is necessary to measure the current on each active area. In general, non-contact testing allows for non-destructive testing of microcircuits during the fabrication process. For example, non-contact testing may be accomplished using an e-beam or a corona discharge.

Non-contact e-beam testing uses an electron beam to probe the device under test but requires operation in a vacuum chamber. Non-contact testing using a corona discharge operates at atmospheric pressure and generates ions by applying a high voltage to a sharp tip. The sharp tip creates a high electric field that acts to ionize the surrounding gas. Ionizers may be alternating current (AC), steady-state direct current (DC) and pulsed DC. AC corona ionization is typically used in heavy industrial applications while steady-state DC and pulsed DC corona ionization are typically used in clean rooms. Issues related to corona ionization include the requirement for high voltages in proximity to the device under test, the need to keep corona emitter points free from particle contamination and erosion and tip erosion.

### SUMMARY OF THE INVENTION

In accordance with the invention, non-contact testing of microcircuits may be accomplished at atmospheric pressure. A photoionization source is used to ionize a specific gas to maximize the ionization current to the device under test. Typically, it is desirable to maximize the ion current to minimize the integration time. An applied voltage may be used to assist the flow of ion current to the device under test (DUT).

### BRIEF DESCRIPTION OF THE DRAWINGS

FIG. 1a shows a conceptual view of an embodiment in accordance with the invention

FIG. 1b shows an embodiment in accordance with the invention.

FIG. 1c shows an embodiment in accordance with the invention.

FIG. 2 shows an embodiment in accordance with the invention using an annular light source.

### DETAILED DESCRIPTION OF THE INVENTION

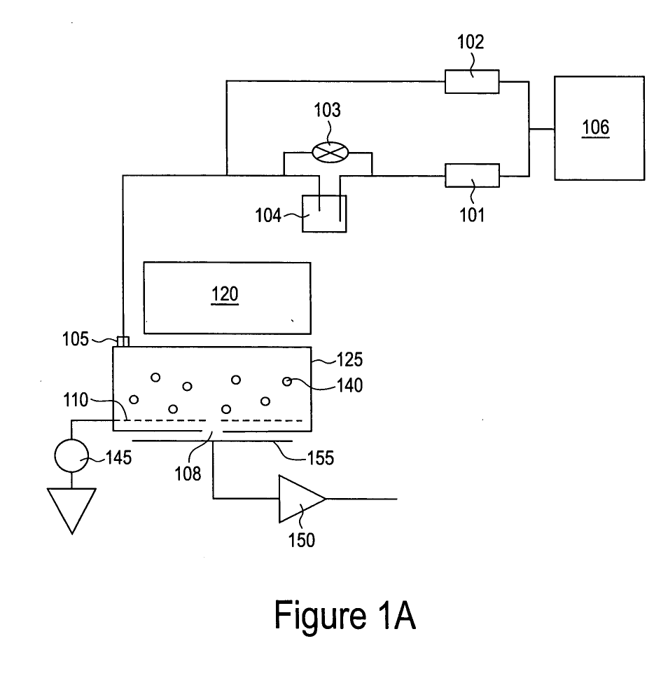

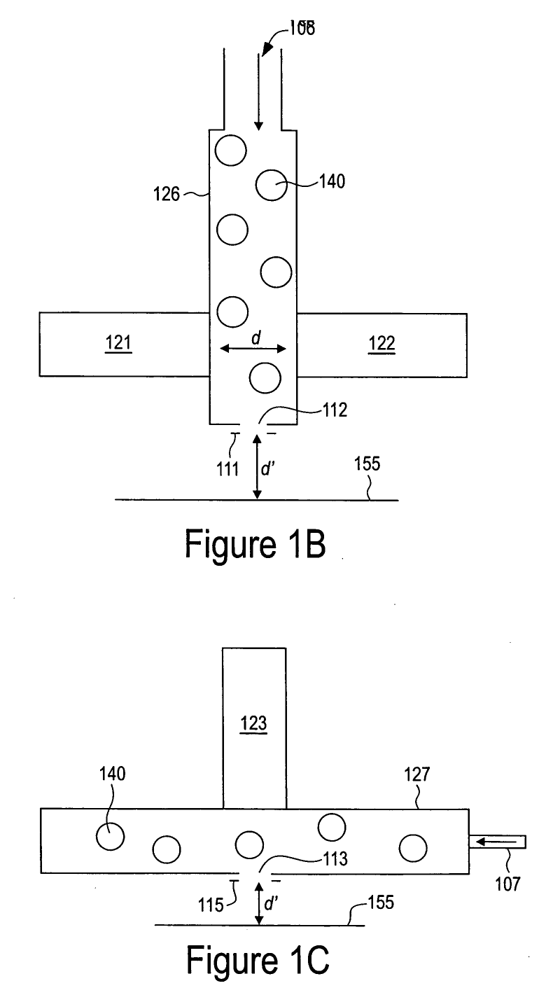

FIG. 1a shows a conceptual view of an embodiment in accordance with the invention. Compact ultraviolet photoionization source 120 is used to ionize gas 140 in ionization chamber 125. Compact ultraviolet photoionization source 120 may be an light emitting diode (LED), LED array or a vacuum ultraviolet photoionization source. Typically, compact ultraviolet photoionization source 120 has an ultraviolet transparent window made from a material such as lithium fluoride. DC voltage 145 is typically applied to electrode 110 in ionization chamber 125 with orifice 108. Electrode 110 typically has an aperture to allow for gas 140 to flow past electrode 110 and through orifice 108 to DUT 155. An applied electric field between electrode 110 and DUT 155 accelerates the charge carriers which are electrons and positive ions created by ionizing gas 140. The electrons and positive ions move in opposite directions, hence, if electrode 110 is the anode and DUT 155 is the cathode, electrons will move to the anode while the positive ions move to the cathode. DUT 155 is typically at zero potential and the ionization current may be measured using transimpedance amplifier 150.

The amount of current is directly proportional to the concentration of gas 140 in ionization chamber 125. Gas 140 is introduced into ionization chamber 125 through gas inlet 105. Gas 140 is typically selected to have an ionization potential that is less than the ultraviolet photoionization source 120 energy and as large a photoionization cross-section as possible. Choices for gas 140 include acetone, ethanol and 2-propenol. For example, a 10.0 eV krypton light source photoionizes any gas molecule with an ionization potential less than 10.0 eV. Hence, a krypton lamp, such as a krypton photoionization lamp available from CATHODEON may be used, for example. Use of a 10.0 eV krypton light source avoids ionization of air and water. However, acetone with an ionization potential of about 9.7 eV is completely ionized. The amount of ionization current is typically controlled by introducing a carrier gas, such as, for example, nitrogen, with a higher ionization potential than gas 140, such as, for example, acetone, from carrier gas reservoir 106 into ionization chamber 125 through inlet 105 along with gas 140. The carrier gas from carrier gas reservoir 106 is typically bubbled into bubbler 104 containing gas 140 prior to introduction into ionization chamber 125. Valve 103 allows bypassing bubbler 104 by the carrier gas. Mass flow controllers 101 and 102 are fluidly coupled to carrier gas reservoir 106 and adjustment of the gas flow rate using mass flow controllers 102 and 101 adjusts the ionization current. Mass flow controller 102 allows dilution of gas 140 with the carrier gas.

For a typical vacuum ultraviolet lamp, the photon flux is of the order 3×10¹⁵ photons/sec/steradian. The active area defined by the size of the transparent window of a vacuum ultraviolet lamp is typically on the order of 8 mm in diameter. With a 45 degree full width half maximum, this results in a net photon flux of about 3.75×10¹⁴ photons/sec. If it is assumed that each photon is converted to an ion, the maximum obtainable ionization current is typically on the order of 60 μA. This value is suitable for use in non-contact testing of microcircuits. The actual value of ionization current that is obtainable depends on numerous factors such as the intensity of the ultraviolet radiation, the absorption cross section of gas 140 in ionization chamber 125, the size of ionization chamber 125, the concentration of ionization gas 140, the lifetime of the ionized species and the flow rate of gas 140 through ionization chamber 125. Because the non-contact testing is performed at atmospheric pressure, the typical choice for gas 140 is a non-toxic gas as otherwise sufficient ventilation needs to be provided.

To estimate the ions which can be generated at DUT 155, the starting point is the kinetic scheme described by the following rate equations:
M+hv→M* (1)
M*→M⁺+e⁻ (2)
R₁=Iₚ−I (3)
R₂=K[M⁺] (4)
where M is the ionizable gas molecule with concentration [M] in moles /liter; M* is the excited gas molecule; M⁺ is positive ion and e⁻ is the electron; hv is the ionizing photon energy; Iₚ is the initial ultraviolet photon flux, K is the rate constant with units of sec⁻¹; and I is the flux in ionization chamber 125. Hence, the number of photons absorbed by gas 140 is R₁.

The probability that a photon will be absorbed can be obtained from the Beer-Lambert Law which describes the attenuation of light intensity through absorbing media as a function of the concentration of the absorbing molecule:
I=Iₚ[1−e^{-σNL}] (5)
where σ is the photoionization cross-section/mole of the gas molecule in meters squared, N is Avogadro's number and L is the absorption length. The resulting ionization current i is given by:
i=IₚFσN[M] (6)
where F is a Faraday (which is the product of the electric charge times Avogadro's number and equal to 96.4853 kilocoulombs). Eq. (6) relates the ion current i to the light intensity Iₚ, concentration of gas [M], photoionization cross-section σ and the absorption length L. In accordance with the invention, it is important to maximize the ion current generation.

In non-contact testing, an objective is to direct the ions that are generated to the device under test. The generated ions can be made to accelerate towards DUT 155 by application of an electric potential. The current-voltage characteristic is determined by Langmuir probe theory. See, for example, Principles of Plasma Diagnostics by I. H. Hutchinson, pp. 55-56. Hence, it is desirable to operate in the electron saturation regime to maximize the current produced at DUT 155.

FIG. 1b shows an embodiment in accordance with the invention. Gas 140 enters ionization chamber 126 through inlet 106 under a pressure in the range from about 0 psi to about 15 psi. Gas 140 flows out through orifice 112 in an ionized state. Orifice 112 is typically on the order of about 200 μm and the flow of gas 140 through orifice 112 has a typical Reynolds number in the range from about 1 to about 1000 where the upper limit is set to prevent formation of a blooming jet. The lower limit for the Reynolds number is limited by the required mass flow. Vacuum ultraviolet lamps 121 and 122 used to ionize gas 140 are positioned opposite one another at the sides of ionization chamber 126 and separated by a distance d, typically on the order of 1.5 mm. The separation distance d is selected to be small enough that the mean free path for the photons from vacuum ultraviolet lamps 121 and 122 is sufficient to ionize gas 140 in the middle of the flow path. Electrode 111, typically having an aperture to match orifice 112 may be positioned over orifice 112. Electrode 111 may be made from a metallized tape such as KAPTON with a deposited metal coating or a thin metal sheet, for example. DUT 155 may be biased positively or negatively and is typically separated from electrode 111 by a distance d′, typically in the range from about 100 μm to about 0.5 mm. Typical potential differences between electrode 111 and DUT 155 are typicallyon the order of about ±10 volts to about ±100 volts for OLED testing and current flows are typically on the order of about 10 μA. Voltages can be on the order of about ±1000 volts for test other devices.

FIG. 1c shows an embodiment in accordance with the invention. Here, gas 140 is introduced into ionization chamber 127 from the side under a pressure on the order of 15 psi or less and vacuum ultraviolet light source 123 ionizes gas 140 from above. The separation between vacuum ultraviolet light source 123 and orifice 113 is typically on the order of the absorption length of the ultraviolet light in gas 140 and may be in the range from about 100 μm to about 2 mm. Only a vacuum ultraviolet light source is required in this embodiment. Gas 140 flows out through orifice 113 in an ionized state. Orifice 113 is typically on the order of 200 μM and the flow of gas 140 through orifice 113 has a typical Reynolds number less than about 100 to prevent formation of a blooming jet. The lower limit for the Reynolds number is limited by the required mass flow. Electrode 115, typically having an aperture to match orifice 113 may be positioned over orifice 113. Electrode 115 may be made from a metallized tape such as KAPTON with a deposited metal coating or a thin metal sheet, for example. DUT 155 may be biased positively or negatively and is typically separated from electrode 111 by a distance d′, typically in the range from about 100 μm to about 0.5 mm. Typical potential differences between electrode 111 and DUT 155 are on the order of about 10 volts to about 100 volts and current flows are typically on the order of about 100 μA. An advantage of this embodiment in accordance with the invention compared to the embodiment shown in FIG. 1b is that vacuum ultraviolet light source 123 is closer to orifice 113 resulting in an increased ion current. A potential issue with the embodiment shown in FIG. 1c is that vacuum ultraviolet light source 123 shines directly on DUT 155 through orifice 113 and this may induce unwanted charge carriers on DUT 155.

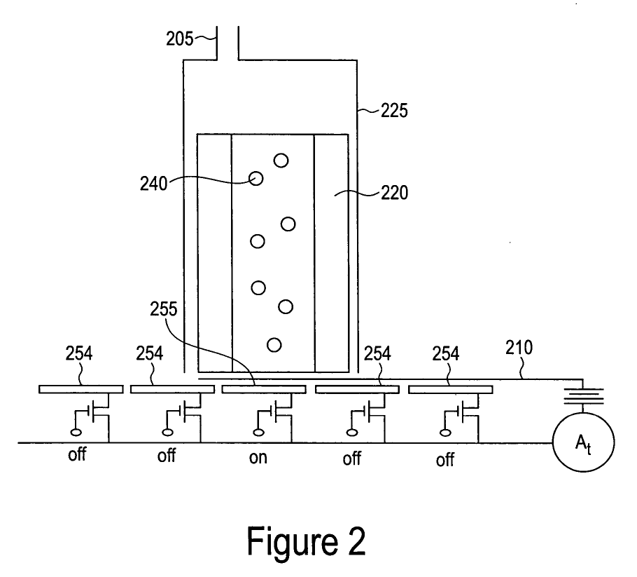

FIG. 2 shows an embodiment in accordance with the invention using annular ultraviolet source 220 to surround gas 240. Annular ultraviolet source 220 has an annular ultraviolet transparent window to enhance current generation by providing a larger interaction region of the ultraviolet light with gas 240. Ultraviolet source 220 is placed inside ionization chamber 225. Gas 240 is introduced into ionization chamber 225 through gas inlet 205. In FIG. 2, DUT 255 is shown as a thin film transistor (TFT) that is part of a TFT array of a flat panel display, for example. Remaining TFTs 254 are off during the test. An applied electric field is created between electrode 210 to DUT 255 to accelerate the charge carriers. DUT 255 is typically at zero potential.

While the invention has been described in conjunction with specific embodiments, it is evident to those skilled in the art that many alternatives, modifications, and variations will be apparent in light of the foregoing description. Accordingly, the invention is intended to embrace all other such alternatives, modifications, and variations that fall within the spirit and scope of the appended claims.

1. An apparatus for non-contact testing of microcircuits comprising:
an ionization chamber comprising a gas inlet and an orifice;
a first ultraviolet light source optically coupled to the interior of said ionization chamber, said first ultraviolet light source capable of ionizing a gas; and
an electrode positioned adjacent to said orifice, said electrode having an aperture collinear with said orifice.

2. The apparatus of claim 1 further comprising a second ultraviolet light source optically coupled to said ionization chamber.

3. The apparatus of claim 1 wherein said orifice has a first diameter on the order of about 200 μm.

4. The apparatus of claim 1 wherein said gas comprises acetone.

5. The apparatus of claim 1 wherein said gas has an ionization potential lower than said first ultraviolet light source.

6. The apparatus of claim 1 wherein said aperture has a second diameter substantially equal to said first diameter.

7. The apparatus of claim 1 wherein said first ultraviolet light source is disposed inside said ionization chamber.

8. The apparatus of claim 7 wherein said first ultraviolet light source is annular in shape.

9. The apparatus of claim 1 wherein said first ultraviolet light source has an ultraviolet transparent window.

10. The apparatus of claim 1 wherein said first ultraviolet source is capable of producing photons having an energy of about 10 eV.

11. The apparatus of claim 1 wherein said electrode is an anode electrode.

12. The apparatus of claim 1 wherein said first ultraviolet source comprises a vacuum ultraviolet source.

13. The apparatus of claim 1 wherein said first ultraviolet source comprises a light emitting diode.

14. A system for non-contact testing of microcircuits comprising:
an ionization chamber comprising a gas inlet and an orifice;
an anode electrode positioned adjacent to said orifice, said anode electrode having an aperture collinear with said orifice;
a first ultraviolet light source optically coupled to said ionization chamber, said ultraviolet light ionizing a gas flowed into said ionization chamber through said gas inlet to create an ionized gas; and
a device under test to receive said ionized gas, where said device under test functions as a cathode electrode to enhance a flow of said ionized gas.

15. The system of claim 14 wherein a potential difference between said cathode electrode and said anode electrode is between about 10 volts to about 100 volts.

16. The system of claim 14 wherein a Reynolds number of said flow of said ionized gas is less than about 100.

17. The system of claim 14 wherein said gas is flowed into said ionization chamber at a pressure of less than about 15 psi.

18. The system of claim 14 wherein said anode electrode and said cathode electrode are separated by a distance in the range from about 100 μm to about 0.5 mm.

19. The system of claim 14 wherein a diameter of said orifice is on the order of about 200 μm.

20. The system of claim 14 wherein said gas is selected from the group containing acetone, ethanol and 2-propenol.

21. The system of claim 14 further comprising a second ultraviolet light source is optically coupled to said ionization chamber.

22. The system of claim 14 wherein said first ultraviolet light source is disposed inside said ionization chamber.

23. The system of claim 14 wherein said device under test is a TFT.

24. The system of claim 14 further comprising a carrier gas mixed with said gas, said carrier gas having a higher ionization potential than said gas.

25. A method for non-contact testing of microcircuits comprising:
providing an ionization chamber comprising a gas inlet and an orifice;
positioning an anode electrode adjacent to said orifice, said anode electrode having an aperture collinear with said orifice;
providing a first ultraviolet light source optically coupled to said ionization chamber, said ultraviolet light ionizing a gas flowed into said ionization chamber through said gas inlet to create an ionized gas; and
placing a device under test to receive said ionized gas, where said device under test functions as a cathode electrode to enhance a flow of said ionized gas.
